(19) United States
(12) Patent Application Publication
(10) Pub. No.: US 2006/0284162 A1
(43) Pub. Date: Dec. 21, 2006

(54) Programmable optical component for spatially controlling the intensity of beam of radiation

(75) Inventors: Ralph Kurt, Eindhoven (NL); Gert Wim T'Hooft, Eindhoven (NL); Robert Frans Maria Hendriks, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/569,683

(22) PCT Filed: Aug. 26, 2004
(86) PCT No.: PCT/IB04/51570

§ 371 Date: Feb. 27, 2006

(30) Foreign Application Priority Data
Sep. 5, 2003 (EP) 03103303.8

(51) Int. Cl. H01L 31/00; H01L 29/06

(52) U.S. Cl. 257/14

(57) ABSTRACT

A programmable optical component (10) for spatially controlling the intensity of a beam of radiation (b), which component comprises a programmable layer which is divided in programmable elements (4,6,8), characterized in that each programmable element comprises bendable nano-elements (8) which are switchable between a non-bend state (8) and a bend state (8′) by means of a driver field. In their bend state the nano-elements absorb radiation. The programmable element may be a switchable diffraction grating or a programmable mask.

The invention relates to a programmable optical component for spatially controlling the intensity of a beam of radiation, which component comprises a programmable layer, which is divided in programmable elements. The invention also relates to an optical scanning device comprising such a component and to a lithographic process wherein such a component is used.

Spatially controlling is understood to mean both controlling the intensity of discrete portions of a beam of radiation incident on the element and controlling the propagation direction of radiation from the beam.

An example of a programmable optical component is a switchable diffraction component, i.e. a diffraction element that can be set in an on-state and off-state, whereby in the off-state the diffraction layer, i.e. the programmable layer, forms a plane parallel layer. Another example of a programmable optical component is programmable mask, for example a lithographic mask.

A well-known diffraction component is an optical diffraction grating, which is widely used in the optical field, either as stand-alone element or integrated with other optical components. A diffraction grating splits an incident beam into a, non-deflected, zero order sub-beam, a pair of deflected first order sub-beams and pairs of sub-beams, which are deflected in higher diffraction orders. There are two main types diffraction grating: amplitude gratings and phase gratings. An amplitude grating comprises grating strips, which absorb incident radiation and alternate with intermediate strips, which transmit or reflect incident radiation. A phase grating introduces a phase, or optical path length, difference between beam portions incident on grating strips and beam portions incident on intermediate strips, because the grating strips have another refractive index or are situated at another level than the intermediate strips.

In view of new applications, for example in miniaturized flexible optical devices or in the optical recording technology, there is a steadily growing demand for diffraction gratings, which are easily switchable and preferably have a substantially smaller grating period than conventional gratings.

Optical lithography is a technology to print a design pattern in a layer of a substrate to configure said layer with device features. This technology is used for manufacturing a device, which comprises usually a number of such configured layers, which layers together provide the required functionality's of the device. The device may be an integrated circuit (IC), a liquid crystalline display (LCD) panel, a printed circuit board (PCB) etc. Conventional optical lithography uses a photo mask comprising a pattern corresponding to the pattern of features to be configured in the substrate layer, which mask pattern is imaged in a resist layer on top of the substrate layer by means of a lithographic projection apparatus.

The manufacture of a photo mask is a time consuming and cumbersome process, which renders such a mask expensive. If much re-design of a photo mask is necessary or in case customer-specific devices, i.e. a relative small number of the same device, have to be manufactured, the lithographic manufacturing method using a photo mask is a costly method. There is thus a need for a mask the pattern of which can easily be changed.

It is an object of the present invention to provide a programmable optical component that can be used amongst others as a programmable grating or in a flexible, in the sense of programmable, lithographic mask. This component is characterized in that that each programmable element comprises bendable nano-elements, which all have their symmetry axis substantially aligned in one direction which direction is switchable between a non-bend state and a bend state by means of a driver field

The driver field may be an electrical field or a magnetic field, dependent on the nature of the bending elements. Substantially aligned in one direction is understood to mean that in principle the symmetry axis of all nano-elements within a programmable element have the same orientation or direction, said one direction, but that small deviations of this one direction are possible, without effecting the optical behaviour of the programmable element. In case of a linear diffraction grating the said one direction is parallel or perpendicular to the direction of the grating strips.

Nano-element is a general term for nanotubes and nanowires, also called whiskers, and small prisms. Nano-elements are very small bodies having a more or less hollow (nanotubes) or filled (nanowires) cylindrical or prismatic shape having a smallest dimension, for example a diameter, in the nano meter range. These bodies have a symmetry axis, the orientation of which determines electrical and optical properties, such as the absorption characteristics of the material wherein they are embedded. When reference is made hereinafter to their orientation, this relates to the orientation of their cylinder axis or prism axis.

Nano-elements have been described in several papers for a variety of materials, such as indium phosphide (InP), zinc oxide (ZnO), zinc selenide (ZnS), gallium arsenide (GaAs), gallium phosphide (GaP), silicon carbide (SiC), silicon (Si), boron nitride (BN), nickel dichloride (NiCL₂), molybdenum disulphide (MOS₂), tungsten disulphide (WS²) and carbon (C).

Particularly carbon nanotubes have been well studied. They are single layer or multiple layer cylindrical carbon structures of basically graphite (sp2-) configured carbon. The existence of both metallic and semi-conducting nanotubes has been confirmed experimentally. Furthermore, it has been recently found that single walled carbon nanotubes (SWCNT) having a thickness of, for example 4-Angstrom aligned in channels of an AIPO₄-5 single crystal exhibit optical anisotropy. Carbon nanotubes are nearly transparent for radiation having a wavelength in the range of 1.5 μm down to 200 nm and having a polarisation direction perpendiculaire to the tube axis. They show strong absorption for radiation having a wavelength in the range of 600 nm down to 200 nm and having a polarisation direction parallel to the tube axis (Li, Z. M. et al., Phys. Rev. Lett. 87 (2001), 1277401-1-127401-4).

Similar properties have been found for nanotubes (or nanowires) other than those consisting of carbon. Nanotubes therefore most conveniently combine the following features. They absorb radiation in a broad range of wavelengths depending on the orientation of the nanotubes relative to the polarisation direction of said radiation and the orientation of the nanotubes can be directed and/or stabilised mechanically and/or by an electrical or magnetic field.

A configuration of linear strips, which comprise nano-elements all having their symmetry axis aligned, i.e. in the same direction, which strip alternate with transparent intermediate strips, thus acts as an amplitude grating for linearly polarised light having its polarisation direction perpendicular to the alignment direction.

In a similar way an optical component comprising a two-dimensional pattern of areas, which are provided with aligned nano-elements (nano-elements areas), which areas alternate with transparent areas thus can be used as a mask for linearly polarized radiation having its polarization direction perpendicular to the alignment direction.

The present invention uses the fact that nano-elements can be modified chemically. For example, carbon nanotubes can be modified by a thiolisation reaction, as described in the paper “Organizing Single-Walled Carbon nanotubes on Gold Using a Wet Chemical Self-Assembling Technique” by Z. Liu et al in Langmuir Vol. 16, No. 8 (2000) p. 3569-3573. Thereby a self-assembled structure is obtained wherein all carbon nanotubes are oriented perpendicular to the surface. The invention uses the insight that these nanotubes or nano-tubes or -elements of other materials can be bent along the field lines of a driver field, for example an electrical field produced by means of electrodes built-in in the programmable component. In a curved state, the nano elements are no longer parallel to the propagation direction of the incident radiation so that they absorb radiation having the proper polarization direction. If the driving field is switched off, the nano-elements resume their initial orientation, i.e. perpendicular to the surface so that the same radiation can pass unhindered. In this way, portions of the programmable component, i.e. programmable elements can be switched between a transparent and absorbing state and vice versa.

It is remarked that DE-A 100 59 685 discloses a device, which comprises a substrate that is provided with a reflective or detecting surface and bendable elements, preferably carbon nanotubes. These nanotubes are connected to a first electrode through direct attachment. If a voltage is supplied to a second electrode, which voltage is different from the voltage on the first electrode and in the bendable elements, these elements will bend their tips towards the second electrode. The elements then form a coating, which locally covers the surface so that the surface locally becomes less reflective or less transmitting and portions of the beam are blocked. If the second voltage is removed from the second electrode, these beam portions are reflected or transmitted again.

The voltage required for bending the nano-tubes in the known device is relatively large, because the tubes should be bent more or less completely, i.e. from an orientation perpendicular to the surface to an orientation substantially parallel to the surface, in order to locally cover the surface completely. Bending over large angles is possible only if the nanotubes satisfy high mechanical requirements.

The programmable component according to the invention differs in at least three features and/or insights from the device of DE-A 100 59 685:

The nano-elements are transparent, at least to a large extent, if oriented substantially perpendicular to the substrate surface. Therefore, in the programmable component of the invention the bendable nano elements are arranged across a complete local surface portion that should be switched between the transparent state and the absorbing state. In the known device the bendable elements are arranged only on top of the electrodes and outside said surface portion in the transparent state. Only if bent over a substantial angle they will cover the surface portion.

In the programmable device of the invention use is made of the fact that the said surface portion becomes absorbing for radiation with the proper polarization direction even if the nano-elements within this portion are bent over a small angle only. In DE-A 100 59 685 the polarization dependent behaviour of the nano-tubes is not mentioned.

In the programmable device of the invention the nano-elements do not form part of an electrode, but are arranged in an electrical or magnetic field between two electrodes. The physical principle governing the behaviour of the nano-elements is their alignment to such a field, so as to obtain an energetically most favourable orientation.

In this way, the nano-elements need to be bent or curved to such degree that they are partly disoriented with respect to the direction of the incident radiation. It is thus not necessary to bend the completely so as to cover a whole surface of a programmable element. In general the bend angle will in the range of 5° to 80°, preferably in the range of 15° to 60° and most preferably in the range of 30° to 45°. The bend angle is defined in a plane determined by the propagation direction and the polarisation direction of the radiation. Preferably, the propagation direction is perpendicular to the substrate.

Since the bend angle is relatively small, less severe mechanical requirements have to be set to the nano-elements, which provides substantial practical advantages. The nano-elements may be shorter than in the known device and the adhesion of these elements is less problematic. The latter is due to, first of all, the reduced bend angle and secondly the reduced strength of the field required for bending the nano-elements. A lower force will be exerted on these elements, especially at the interfaces of these elements and the surface, which interfaces are mechanical weak portions.

Compared with the device of DE-A 100 59 685, the programmable component of the invention provides two advantages. The first advantage is that it allows a high degree of miniaturization, because no space needs to be reserved for the nano-elements, because they are arranged across the whole surface area of a programmable element. In the device of DE-A 100 59 685 the nano-elements should be arranged outside the areas which should pass or block radiation, and the areas occupied by the nano-elements can not be used for other purposes. The second advantage is that the field strength of the driving field is considerably smaller.

With respect to its construction the programmable optical component of the invention may be further characterized in that it comprises a substrate, an electrode configuration of first and second electrode portions, which configuration defines the programmable element areas, and a nano-elements embedding medium on top of the electrode configuration.

This is the simplest embodiment of the programmable component, which is suitable for most applications.

Preferably the programmable component is further characterized in that an electrically isolating layer is arranged between the electrode configuration and the nano elements embedding medium.

The isolating layer prevents electrical shorts and subsequent electrical current flows, which may affect accurate controlled switching. Preferably the isolating layer is a dielectric layer.

Bending of the nano-elements is based on dipole interaction or on magnetic interaction, dependent on the type of nano-elements. This is quite different from the electrostatic bending used in the device of DE-A 100 59 685. For electrostatic bending the bendable elements should be electrically connected to and preferably directly attached to the electrodes. This introduces the risk of electrical shorts and of burning away of the bendable elements, particularly if these elements consist of organic material or if, for example carbon nanotubes are used.

The dielectric layer may comprise any inorganic or organic dielectric material, such as aluminium oxide, silicon oxide, silicon nitride or a so-called high-K material.

The programmable optical component is preferably further characterized in that the first and second electrode portions form a pair of interdigitated electrodes.

This allows high generating the electrical field with high efficiency. As the electrodes are interdigitated a channel is formed between them. The width of the channel may be small whilst at the same time the channel may be very long. Thus, a relative low voltage is sufficient to provide the electrical field strength (V/μm) required for bending.

If interdigitated electrodes are used, the direction of the nano-element bending will not be the same at all locations; there will be bend angles +γ and bend angles −γ.

However, this has no consequences for the degree of absorption.

Preferably the programmable component is further characterized in that the electrode configuration is embedded in a planarizing layer and the nano-elements embedding layer is arranged on the planarizing layer.

The electrode configuration may be integrated with the substrate and covered with a planarizing layer so as to provide a planer surface for the nano-elements. The nano-elements embedding medium may be air, but preference is given to a programmable component which is characterized in that the nano-elements embedding medium is an insulating fluid.

Suitable fluids for this application are liquids, vapours and gases. Preferably the fluid is viscous to a certain extent so that it can provide a counterforce. This allows a more accurate and mechanically stabilized bending of the nano-elements. Another advantage of such a fluid is that it prevents any sticking of the nano-elements to each other. A person skilled in the art may adapt the fluid material and viscosity according to the specific application of the programmable component.

In general, the bendable nano-elements will return to their initial, unbend position after removal of the electrical or magnetic field. This return may be influenced by the stiffness of the nano-elements and their adhesion contact, i.e. the contact of the nano-elements with the substrate.

Return of the nano-elements to their initial, non-bent, state can be forced by reverting the orientation of the electrical or magnetic field during a time period smaller than the period the field should be present to set the nano-elements in the bent state. A forced return without field reversion becomes possible if the programmable element is characterized in that a second electrode configuration is arranged at the side of the nano-elements embedding medium remote from the medium side facing the substrate.

Different types of nano-elements as defined in claims 8-13 may be used in the programmable component. The nano-elements may be carbon nanotubes, metallic or semiconductor nanowires, metallic or semiconductor nanotubes or magnetic nanowires or nanotubes filled with any (ferro-)magnetic material. The diameter of the nano-elements is preferably less than 150 nm, more preferably, less than 50 nm and further preferably, between 0.3 nm and 10 nm. The length of nano-elements is preferably in the range from 5 nm to 10 μm, more preferably in the range from 10 to 500 nm and furthers preferably in the range from 50 to 300 nm.

Care should be taken that mutual screening of the nanowires is suppressed as much as possible. Mutual screening is the effect that one of the nanowires within a given surface area attracts the major part of the local electrical field so that less electrical field remains for the other nanowires within this surface, i.e. the other nanowires are shielded form the field. In this aspect, semiconductor nanowires are preferred to metallic nanowires, because they show less mutual screening.

Nano-elements, particularly carbon nanotubes may be chemically functionalised so as to improve their attachment, or adhesion, to the substrate surface. In this way carbon nanotubes can be attached to a gold surface, as described by Liu et al in the above cited paper in Langmuir. A suitable functionality for an oxide surface (SiO₂, Al₂O₃ or glass) is, for example SiCl₃ or Si(OR)₃, with R alkyl, preferably isopropyl or butyl or phenyl. A suitable functionality for a gold surface is a thiol or thiol-ether (Z-SH, Z-S—S-Z, Z-CH₂—S—CH₂-Z, with Z the carbon nanotubes). A suitable functionality for a platinum surface is a base, such as —OH or —NH₂. A suitable functionality for a silver- or SiO₂ surface is an acid, such as —COOH. A suitable functionality for a non-oxidized silicon surface is a 1-ethylene-group (—CH═CH2). A suitable functionality for a mica surface is a phosphide group or an alkyldiphonic acid (PO₃²⁻).

Nanowires and nanotubes can also be produced by growing them in a template. The template allows defining the pattern of nano-elements in an easy and good-controllable way, as is described by Schönenberger et al. in J. Phys. Gem. B, Vol 101 (1997), 5497-5505. The template is provided with pores which have a diameter preferably in the range from 3 nm to 200 nm, more preferably in the range from 5 nm to 15 nm. Pores having uniform diameters can be produced with conventional techniques. The distance between the pores may be of the order from one to ten times the pore diameter. The pores may be substantially perpendicular to the surface and be laterally ordered by providing suitable conditions or by local surface pre-treatment by means of for example an E-beam or imprinting. The nanowires can be grown by means of known methods, such as electrochemical growth and the VLS (vapour-liquid-solid) method. Electrochemical growth of the nanowires is possible for III-V materials, II-VI materials and metals. The VLS method is suitable, for example, for III-V materials and for carbon nanotubes and is generally performed at temperatures in the range from 400° to 800° C., as is known from the paper of Morales and Lieber in Science, Vol 279 (1998), 208-211. After the growth, the template is at least partially removed, for example, by means of wet- or dry etching.

Also alternative growth method can be used. Furthermore, nanowires may be produced by etching a semiconductor substrate according to a required pattern. Anodic etching of a semiconductor substrate, particularly a silicon substrate, may be used to produce an array of a large number of semiconductor nanowires.

The programmable optical component may be further characterized in that each nano-element is arranged in an insulating region.

In this embodiment no insulating layer between the electrode configuration and the nano-elements is needed. The insulating regions can be produced by using the VLS method and changing the gas composition in the chamber during growth of the nano-elements. A growth process wherein process parameters are changed during the process is known as segmented growth.

The programmable component may be characterized in that it is a transmission component.

In this embodiment both the substrate and the electrode configuration should be transparent. Transparent electrical conductive materials, which are suitable for the electrodes are very thin metal layers and particularly oxide conductors, such as indium-tin-oxide (ITO), ruthenium oxide, lead ruthenium oxide (Pb₂Ru₂O₇), strontium lanthanum cobalt oxide, rhenium oxide and other materials, such as known from EP-A 689294. Alternatively transparent electrically conductive organic materials, such as poly-(3,4-ethylenedioxy)thiophene (PEDOT) or polyaniline (PAN) may be used.

Alternatively the programmable optical component may be characterized in that it is a reflective component. Such a component may be the same as a transmission component, but has a reflective substrate or a reflective layer arranged between the substrate and the electrode configuration.

Depending on the shape and the pattern configuration of the programmable elements, the programmable component can be used for different applications. For a first application the component forms a switchable diffraction grating, wherein the programmable elements are elongated and constitute grating strips, which alternate with nano-elements less intermediate strips.

By switching the programmable elements on and off, the grating function can be set on and off. Such a switchable grating can be used in an apparatus, such as an apparatus for reading and/or writing an optical record carrier, wherein two beams travel along a same path, which comprises a grating for only one of the beams.

The programmable grating may be a linear grating, wherein the programmable elements all extend in the same direction.

Alternatively the programmable grating may be a two-dimensional grating having first programmable element extending in a first direction and second programmable elements extending in a second direction, different from the first direction, which first programmable elements are arranged in first surface areas and which second programmable elements are arranged in second surface areas alternating with the first surface areas.

Another type of programmable component according to the invention is a switchable Fresnel lens, wherein the programmable elements have an annular shape and constitute Fresnel lens zones, which alternate with nano-elements less intermediate annular strips.

For another application the component forms a mask having a changeable mask pattern, wherein the programmable elements constitute pixels, which are arranged in a two-dimensional structure.

By individually switching the programmable elements on and off an arbitrary mask pattern can be created. When using such a programmable mask in a process of manufacturing IC's or other devices by means of lithography, this process becomes flexible and very suitable for producing devices in small quantities or customized devices.

The invention also relates to a device for scanning an optical information carrier of a first type having a first information density and an optical information carrier of a second type having a second information density, which device comprises a radiation source unit supplying a first radiation beam having a first wavelength for cooperating with the first type information carrier and a second radiation beam having a second wavelength for cooperating with the second type of record carrier, and an objective system for focussing the first and second beam to a first and second scanning spot in the information layer of the first and second type information carrier. This device is characterized in that it comprises at least one diffraction grating as described herein above.

This diffraction grating may be a beam-combining diffraction grating and may be arranged in at least one of the following optical path portions:

between the radiation source unit and the objective system,

between the objective system and a radiation-sensitive detection system for receiving radiation from the information layers.

The diffraction grating may also be a three-spots diffraction grating, which is arranged between the radiation source unit and the objective system.

The invention also relates to a lithographic process for producing device features in at least one layer of a substrate, which process comprises transferring a mask pattern into the substrate layer by means of a projection apparatus. This process is characterized in that use is made of a programmable mask as described hereinbefore.

The projection apparatus is understood to mean an apparatus comprising a projection system for imaging a mask pattern arranged at one side of the projection system onto a substrate arranged at the other side of this system, but also proximity printing apparatus wherein the mask and the substrate are arranged close to each other.

These and other aspect of the invention will be apparent from and elucidated by way of non-limitative example with reference to the embodiments described hereinafter and illustrated in the accompanying drawings. In the drawings:

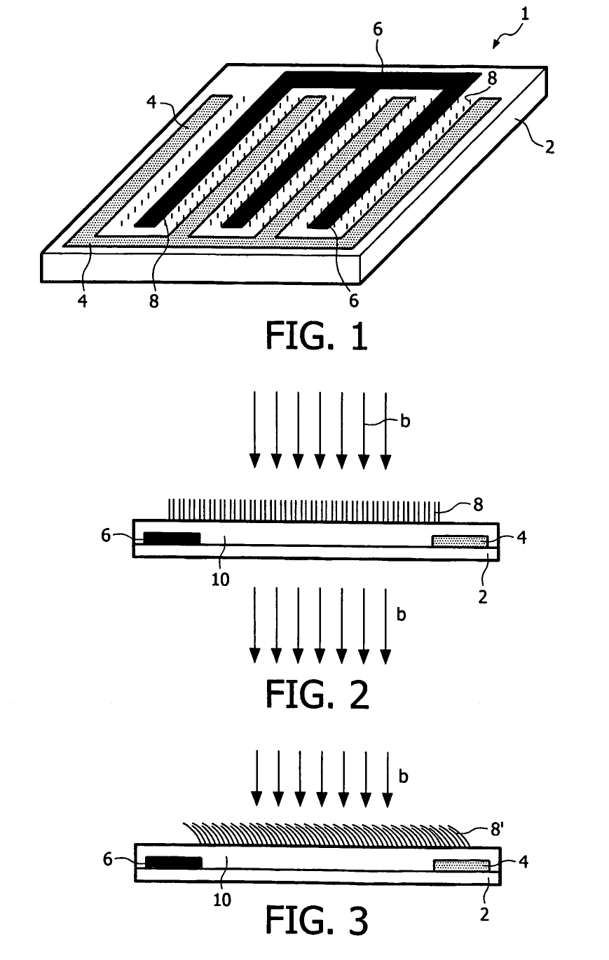

FIG. 1 shows a perspective view of a portion of a first embodiment of a programmable component according to the invention.;

FIG. 2 shows across-section of a programmable element of the component with the bendable nano-elements in their non-bended position;

FIG. 3 shows this element with the bendable nano-elements in their bended position:

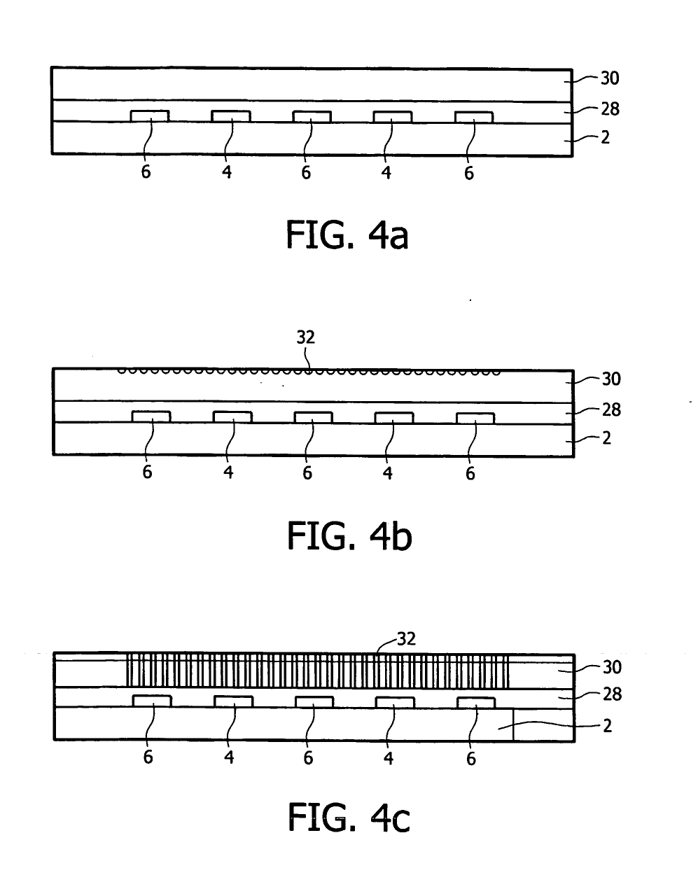

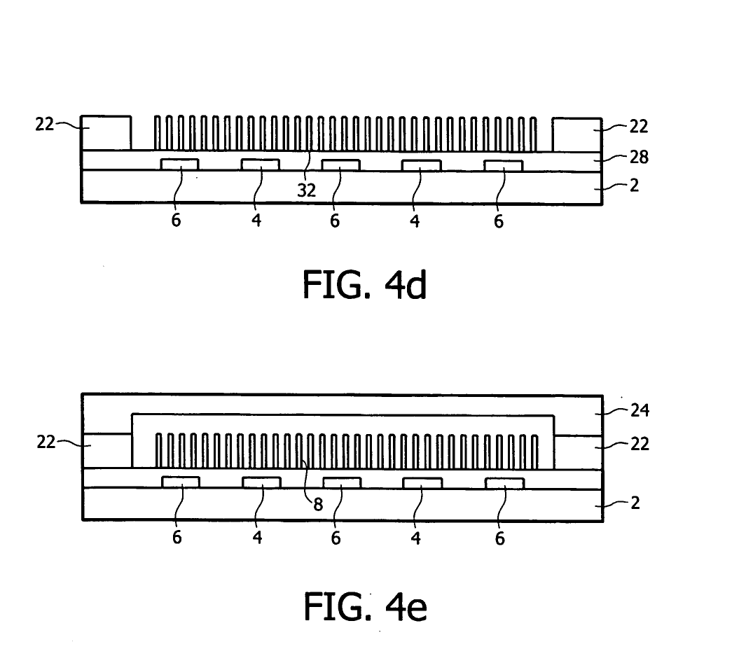

FIG. 4a-4e shows a cross-section of a second embodiment of the programmable component and some of the manufacturing steps;

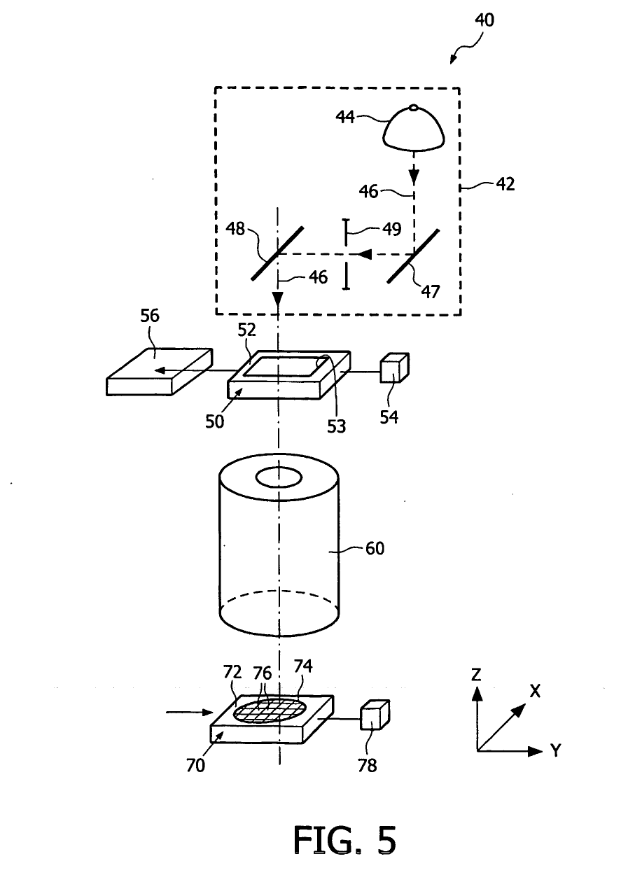

FIG. 5 shows a diagram of a lithographic projection apparatus with a programmable mask according to the invention;

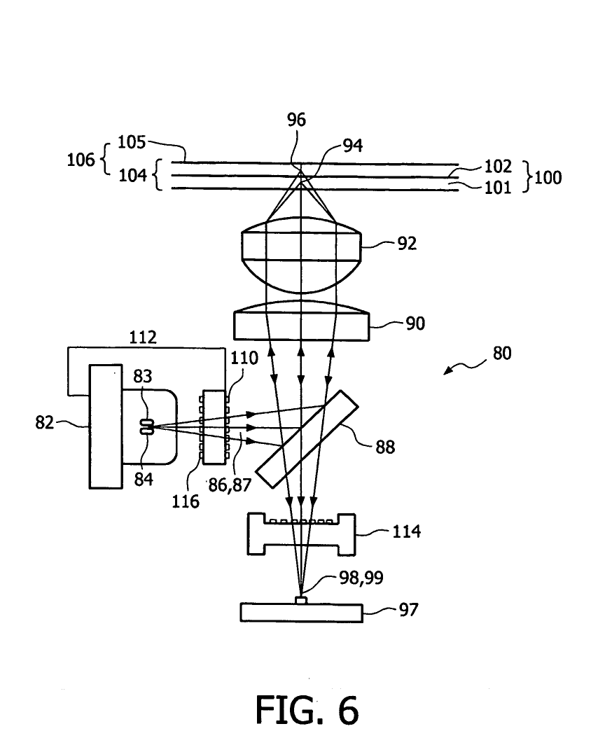

FIG. 6 shows a diagram of a device for scanning an optical record carrier, in which device one or more diffraction gratings according to the invention may be used, and

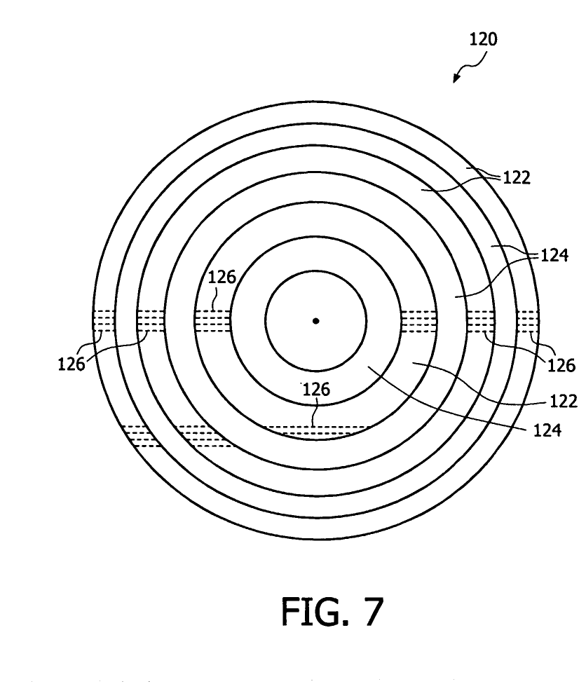

FIG. 7 shows a Fresnel lens according to the invention.

The Figs. are not drawn to scale and are pure schematic. The same reference numbers in different Figs. refer to the same elements.

The component, which is partly shown in FIG. 1, comprises a substrate 2, for example a transparent substrate such as a glass or a transparent-plastic substrate. The upper side of the substrate is provided with first and second electrodes 4 and 6, respectively and with bendable nano-elements 8, which are arranged between the electrodes. The electrodes 4 and 6 may be interdigitated, i.e. portions of first electrode are arranged between portions of the second electrode. Such an electrode structure is very suitable to produce a diffraction grating, whereby the strips with bendable nano-elements form grating strips and the electrode portions the intermediate strips. The electrodes 4 and 6 shown in FIG. 1 has four fingers and three fingers, respectively. However, the number of fingers can be chosen freely and in practice will be much larger for a diffraction grating. The electrodes are transparent and may be made of, for example indium tin oxide (ITO).

As shown in the cross-section view of FIG. 2, the electrode configuration 4,6 may be covered by a dielectric layer 10, for example a SiO₂ layer. This layer can be coated by a sol-gel technique, whereby a solution of tetraethoxyorthosylicate is applied and subsequently cured. The dielectric layer 10 has a double function. Firstly, it provides a planar surface for the nano-elements, which simplifies placing the bendable nano-elements 8 in position afterwards. Secondly it forms an insulating layer between the electrodes 4, 6 and the nano-elements. In this way, the position of the nano-elements, straight or curved, will be determined by the electrical or magnetic field, and not by direct contact with the electrodes. The dielectric layer 10 can be supplied by chemical vapour deposition or any other deposition method. In case such a deposition method does not result in a planar layer surface, an additional planer layer may be supplied.

In this embodiment the nano-elements 8 are carbon nanotubes, which have been functionalised with Si(OR)₃, groups, wherein R is methyl. Functionalization of carbon nanotubes with suitable end groups per se is known from the above cited paper in Langmuir, Vol 16 (2000), pp 3569-3573. Therein, single walled carbon nanotubes of desired length are suspended with ultrasonification in alcohol. The carbon nanotubes have carboxylic acid end groups by oxidation. This end group is substituted through a chemical reaction with Si(OR)₃. In order to obtain a patterned deposition, the substrate is covered with a photoresist material, which is developed according to the desired pattern. Then the photoresist material and the substrate undergo a plasma treatment process so as to make the substrate more hydrophilic and the photoresist more hydrophobic. A suitable treatment process is a sequence of an oxygen plasma treatment, a fluor plasma treatment and an oxygen plasma treatment. Bundles of carbon nanotubes will align across the surface due to the hydrophobic interactions between the individual carbon nanotubes.

Instead of by means of a photoresist, a mask of another material may be used to obtain the required pattern. The pattern may also be obtained by burning away carbon nanotubes from portions of the surface, for example by means of a laser beam having sufficient intensity.

The resulting component is a transmission component, as shown in FIG. 2. A beam of radiation b passes the component unhindered, because the nanotubes are aligned parallel to the propagation direction of the radiation, which in this case is perpendicular to the surface. This is the case if no voltage is supplied to the electrodes, i.e. no electrical field is present. If the electrical field is switched on, the nano-elements will bend and become curved elements 8′, as shown in FIG. 3. The curved nano-elements now cover at least a substantial portion of the areas between the electrodes 4 and 6 and absorb that component of the beam b that has a polarization direction parallel to the tangent of the curved nano-tubes. The absorption of an incident beam b will be maximum if the beam is linearly polarized beam having its polarization direction tangent to the curved nano-tubes.

The nano-tubes can be bended by means of an electrical field having a field strength in the range from 0.1 to 5 Volt/μm. The voltage for generating the electrical field may be a DC voltage. However, it has been demonstrated that for the larger values of the voltage range, the best results are achieved if the voltage is an AC voltage, preferably having a frequency in the range from a few Hz to some KHz, more preferably about 50 Hz.

The strip shaped electrodes 4 and 6 are substantially longer than shown in FIGS. 2 and 3, i.e. their lengths is substantially larger than the distance between them. Since these electrodes are transparent and the nano-tubes regions between them absorb radiation id the component is activated, i.e. a driving field is present, the component acts as a diffraction grating for radiation having a suitable polarization direction. The particularity of this grating is that the grating function can be switched on and off, simply by switching the electrical, or another driving field.

The transmission grating of FIGS. 2 and 3 can be converted into a reflective grating by using a reflective substrate or by arranging a reflective layer between the substrate and the electrode configuration. Alternatively both the substrate and the electrodes can be made reflective.

FIG. 4e shows a cross-section of another embodiment of the new component, which can be used as a programmable, or flexible, mask for example in photolithography. The programmable elements, each consisting of one or two pairs of opposed electrode portions 4, 6 and nano-elements areas there between, now constitute picture elements (pixels), which together form a pattern, such as an IC pattern image that is to be projected in a photoresist layer on top of a semiconductor substrate. The image content is determined by the state, switched on or off, of the individual pixels. Such a pixel usually consist of one programmable element under circumstances a pixel may comprise more than one programmable element. The pixel configuration is now two-dimensional.

FIGS. 4a-4d shows stages in the manufacture of the component shown in FIG. 4e. The electrodes 4 and 6 are interdigitated and each portion of an electrode is connected with the other portions thereof, in a similar way as shown in FIG. 1. The nano-elements in this embodiment are nanowires, which have been grown electrochemically and may be arranged in a cavity formed by a spacer 22 and a cover 24, for example of plastics.

The bendable nanowires 26 may be supplied by means of template growth, as will be explained with reference to FIGS. 4a-4d. FIG. 4a shows an intermediate product comprising some layers and produced by means of a semiconductor manufacturing technique. This product comprises a substrate 2, for example of glass, electrodes 4 and 6 and an etch-stop layer 28, for example of silicon nitride. The layer 28 is covered by an aluminium layer 30.

FIG. 4b shows the start of formation of pores in the aluminium layer 30, by means of anodised etching of the aluminium, whereby aluminium is converted into aluminium oxide (Al₂O₃). The anodised etching of aluminium is a conventional technique. The pores 32 are deepened by means of O₂ evolution until the reach the etch stop layer 28, as shown in FIG. 4c. This result in an aluminium layer with, for example 30% porosity. The pore density is, for example of the order of 5.10¹⁰/cm².

FIG. 4d shows the product after some further process steps, which are known per se, have been carried out and nanowires have been grown. Cu nanowires can be grown from CuSO₄, Au nanowires can be grown from K₄Au(CN)₃, Ni nanowires can be grown from NiSO₄/NiCl₂ and CdSe nanowires can be grown from CdCl₂ and H₂SeO₃ in water. In the process stage shown in FIG. 4d also the aluminium matrix has been dissolved at least partially. Preferably, the lower portion, some nano meters thick, of the aluminium matrix is retained. In this way an improved adhesion of the nanowires to the substrate is obtained. In order to retain the spacers of Al₂O₃, a mask is used so as to etch selectively. These spacers 22 are porous, but sufficient strong to be used as a wall.

As shown in FIG. 4e, a cover 24 may be arranged on top of the spacer 22 and attached with a glass frit. If desired the cover 24 may be provided with an electrode layer on one of its surfaces, preferably the surface facing the nano-elements. This electrode may be used for quick return of the nanowires from the bent state into the non-bent state. Another electrode may form part of the substrate. Furthermore, the cavity containing the nano-elements may be filled with a liquid.

Alternative methods for providing nanowires with template growth may be used as well. For example, a layer of a noble metal, such as gold or platinum can be deposited on top of the silicon nitride layer 28. Such a layer acts as an etch stop layer and at the same time can be used as a plating base. The layer of the noble metal can be configured according to the required pattern and in the end be used as an additional electrode. In such an embodiment the layer of noble metal is present only in the regions between the electrodes 4, 6 and the nano-elements do not extend to the top of the electrodes.

Alternatively, the layer of noble metal, or any other metal such as nickel or copper may be removed after the nanowires have been supplied and the aluminium matrix has been removed. This step is particularly suitable if the nanowires comprise a semiconductor material, which has been deposited electrochemically or with the VLS method. The layer of noble metal then can be etched selectively with respect to the nanowires, i.e. the complete regions with nanowires acts as an etch mask. The mechanical stability of the nanowires is not a specific problem for this embodiment, because a certain mechanical stability is generally required when arranging bendable elements.

In an alternative embodiment the electrodes 4, 6 are moved to the opposite side and the layer of noble metal is deposited directly on top of the substrate 2. the opposite side may be the inner surface of the cover plate 24.

Most preferred is the embodiment wherein use is made of the substrate transfer method, i.e. the original substrate is finally removed and the aluminium matrix is dissolved from the substrate side instead of from the top side. After growing of the nanowires and before dissolution of the aluminium matrix, a layer of dielectric material and the electrodes are arranged on top of the matrix. This can be done by means of any thin-film process, such as wet-chemical deposition, sputtering and chemical vapour deposition. Further interconnect layers may be deposited, as well as a protective cover layer of, for example glass or a polymer. Then the product is turned upside down and the substrate, the etch-stop layer (alias plating base) and the aluminium matrix are removed. The glass substrate can be removed by irradiating an UV-releasable glue layer, which is arranged between the glass substrate and the etch-stop layer, with actinic UV radiation.

The pattern of nanowires can also be produced by means of a catalytic CVD growth process.

The processes described hereinabove for the production of nanowires can also be used for the production of nanotubes.

The programmable mask of FIG. 4e can be used with great advantage in a lithographic projection apparatus. FIG. 5 shows a very schematic perspective view of such an apparatus. The main modules of this apparatus are: an illumination system 42, a mask table 50, a projection system 60 and a substrate (wafer) table 70. The illumination system 42 comprises a radiation source 44, such as a Hg lamp or excimer laser, for supplying a projection beam 46 of, for example UV radiation or extreme UV (EUV) radiation. The projection beam is guided to the mask table via folding mirrors 47 and 48 and a diaphragm 49. The illumination beam further comprises means (not shown) for making the beam intensity uniform throughout its cross-section and beam shaping lenses and/or mirrors. The apparatus may also use other types of radiation such as X-rays or a charged particle beam.

The mask table 50 is provided with a mask holder 52 for holding a mask 53, e.g. a reticle. This mask comprises a mask pattern that is to be projected on the substrate by means of the projection beam 46. This projection is performed by the projection system 60, which may be lens system, a mirror system, a system comprises lenses and mirrors, or a charged particle imaging system. The projection system images an illuminated portion of the mask 53 onto a target portion (die) 76 of the substrate 74. The substrate, or wafer, is accommodated in a substrate holder 72, which forms part of the substrate table 70. The substrate is coated with a resist layer in which the image of the mask pattern is formed. In a stepper type apparatus the whole mask pattern is illuminated and projected onto a target portion 76. To expose all target portion with the mask pattern, the substrate table is, between successive exposures, stepped, i.e. moved over predetermined distances in the X- and Y-direction, by driving means 78, In a step-and-scanning type apparatus a small portion (rectangular or annular segment) of the mask pattern and a corresponding portion of the target are illuminated at any time. To illuminate the whole mask pattern and to expose the whole target portion 76, the mask table and substrate table are moved (scanned) synchronously with respect to the illumination system and the projection system. To allow such scanning the mask table should be provided with driving means and the driving means 78 for the substrate table should be adapted.

Conventionally the mask comprises a fixed mask, which has been manufactured by a mask manufacturer upon specification of the designer of the device to be manufactured and of the patterns of the different layers of this device. A mask is a costly component and becomes relatively more costly if the number of devices to be manufactured by means of the mask decreases. Moreover in the pilot manufacture of a device often re-design of the mask pattern is necessary, which results in a considerable increase of time and costs.

According to the invention the conventional mask 53 can be replaced by a programmable mask 20 as described herein above and by including a controlling device 56 for this mask, as shown in FIG. 5. The controlling device may be a separate module, for example a microcomputer, or may form part of the control module, which controls all functions of the lithographic apparatus. In this way, the photolithographic technology becomes very flexible, because the mask pattern can be changed at any moment, simply by switching on or off its individual pixels, or programmable elements, according to the required mask pattern. In a pilot manufacturing process the mask can easily be corrected and need not to be replaced if correction are needed. The mask is suitable for the manufacture of very different types of devices and allows considerably reducing the cost for small quantity devices such as customized devices.

The programmable mask can also be used in a proximity printing apparatus, wherein no projection system 60 is used and the mask and the substrate are separated by only a small air gap.

A special advantage of the use of the programmable mask in lithography is that the mask is not sensitive to projection radiation, such as deep UV (DUV) radiation.

The switchable grating described hereinabove can replace a conventional amplitude grating and shows the advantages that it is easy and cheap to manufacture and shows a high contrast between the grating strips and the intermediate strips. The capabilities of this grating can be used to the optimum extent in an optical system or device wherein two radiation beams are used, which beams follow the same radiation path, whilst only one of the beam should undergo diffraction and the other not. This can be achieved by arranging the novel grating in the common radiation path and switching the grating on for one beam and off for the other beam.

An example of such an apparatus is an optical scanning device for reading and recording an optical information carrier of a first type having a first information density and an optical information carrier of a second type having a second information density. This device comprises a radiation source unit supplying a first radiation beam having a first wavelength for cooperating with the first type of information carrier and a second radiation beam having a second wavelength for cooperating with the second type of record carrier and an objective system for focussing the first and second beam in the information layer of the first and second type record carrier, respectively.

The published patent application US2002/0027844A1 describes an example of an optical scanning device for scanning in a first mode of operation a first record carrier having a first, HD, information layer and for scanning in a second mode of operation a second type of record carrier having a second, LD information layer, which device may comprise several diffraction gratings. HD stands for high density and a high-density record carrier is for example a record carrier of the DVD (digital versatile disc) type. Such a record carrier is scanned by a HD beam. LD stands for low density and a low-density record carrier is for example a record carrier of the CD (compact disc) type. Such a record carrier is scanned by a LD beam. The HD beam has a smaller wavelength, for example 650 nm, than the LD beam, for example 780 nm, so that a same objective system focuses a HD beam to a smaller spot than a CD beam.

FIG. 6 shows an embodiment of such type of scanning device, which is also called combination (combi) player. The optical path of the device 80 comprises a radiation source 82 in the form of a two wavelength diode laser package. This is a composed semiconductor module, which has two elements 83 and 84 emitting radiation beams of different wavelengths 86 and 87, respectively. This module may comprise a single diode laser chip having two emitting elements or two diode laser chips arranged in one package. Although the distance between the emitting elements is made as small as possible, the chief rays of the beams 86 and 87 do not coincide. Nevertheless in FIG. 6 the HD beam 86 and the LD beam 87 are represented by a single radiation beam for sake of clarity.

The beam 86 or 87 emitted by the radiation source unit 82 is incident on a beam splitter 88, for example a semi-transparent mirror, which reflects part of the beam to a collimator lens 90. This lens converts the divergent beam into a collimated beam. This beam passes an objective lens system 92, which focuses the HD beam to a scanning spot 94 and the LD beam to a scanning spot 96.

The HD record carrier 100 to be scanned by the spot 94 comprises a transparent layer 101 having a thickness of, e.g. 0.6 mm and an information layer 102. The LD record carrier 105 to be scanned by the spot 96 comprises a transparent layer 106 having a thickness of, e.g. 1.2 mm and an information layer 107.

Radiation of the beam 86 or 87 reflected by the respective information layer returns along the optical path of this beam, passes the beam splitter 88 and is converged by the collimator lens 90 to a spot 98 and 99 respectively on a radiation-sensitive detection system 97. This system converts the beam into an electrical detector signal. An information signal representing information stored in the information layer being scanned and control signals for positioning focus 94 or 96 in a direction normal to the information layer 102 or 107 (focus control) and in a direction normal to the track direction (tracking control) can be derived from the detector signal.

In a device of the type schematically shown in FIG. 6 diffraction grating may be used at different positions in the radiation path and for different purposes. A beam combining grating may be arranged close to the radiation source unit 82 to diffract one of the beams 86,87 such that its axis coincides with that of the other beam, which is not diffracted so that the two beams follow exact the same path in the device. The requirement that the grating should be effective for only one of the beams can be satisfied by using a grating according to the invention and switch this grating on, i.e. bend the nano-elements in this grating, together with the radiation source 83 or 84, which supplies the beam that should be diffracted. Care should be taken that this beam is a linearly polarized beam having its polarization direction parallel to the mean direction of a bended nano-element. FIG. 6 shows such a schematically represented grating 110 and a line 112 between this grating and a control input of the source unit 82, which line symbolically represent the simultaneous switching of the grating and the relevant radiation source.

A beam combining grating may also be arranged between the beam splitter 88 and the radiation sensitive detection system 97 to diffract one of the beams reflected by the relevant information layer such that this beam becomes coaxial with the other beam reflected by the other information layer. The spots 98 and 99 formed by these beams on the radiation-sensitive detection system than have the same position so that the same detection element can be used for the two beams. Since only one of the beams should be diffracted and the other not, a diffraction grating according to the invention can advantageously be used for this purpose. Such a grating is schematically represented by element 114 in FIG. 6.

In a device of the type shown in FIG. 6 track following, i.e. keeping a scan spot on the information track that is momentarily scanned, can be carried out by means of the three-spots method. A device using this method comprises a diffraction grating that splits a scanning beam into a main beam forming a main spot in the information layer and two auxiliary beams forming two satellite spots in the information layer. The main spot is used for reading and/or recording information and the satellite spots are used for measuring the position of the main spot with respect to the centre line of the information track. If the three-spots method is used for only one of the beams, for example a beam that records information, the three spots grating should be invisible for the other beam. This can realized by replacing a conventional diffraction grating by a switchable grating according to the invention, which grating is switched off during the presence of said other beam. Such a three-spots grating 116 can be arranged between the source unit 82 and the beam splitter 88. If a beam combining grating 110 is also present, the gratings 110 and 116 can be arranged at different side of one substrate 118, as shown in FIG. 6.

The device may also comprise two three-spots diffraction gratings, one for each of the beams, for example in case the two beams should record information in their respective information plane. In that case, at any time during operation of the device one of the three-spots gratings is switched on and the other switched off, simultaneously with the beam for which the grating is destined.

Two applications of the invention has been described: a programmable lithographic mask and a switchable linear diffraction grating for the optical recording technique. This does not mean that the invention is limited to these applications. The switchable linear grating according to the invention can be used in any optical system wherein two beams travelling along the same path are used, one of which has to be diffracted and the other not and, more general, in any optical system wherein a switchable grating is used. The programmable grating may also be a two-dimensional grating, i.e. a grating having first grating strips and second grating strips, which differ from each other in that they extend in different directions, for example mutually perpendicular directions. The first grating strips, together with their intermediate strips, are arranged in first surface areas and the second grating strips, together with their intermediate strips, are arranged in second surface areas, which alternate with the first surface areas. The first and second surface areas may be square-shaped and the borders of these areas may be parallel or diagonal to the borders of the whole grating.

The invention can not only be used in a diffraction grating, but in any diffraction element which is composed of first areas, strip- or otherwise shaped, which alternate with second areas, which first and second areas show different absorption. A well known example of such a diffraction element is a Fresnel (zone) lens. FIG. 7 shows an embodiment of a Fresnel lens 120 according to the invention. This lens is composed of first annular shaped strips 122, which alternate with second annular shaped strips 124. The first strips comprises nano-elements 126, whilst the second strips do not. The nano-elements are shown in bended position, i.e. the lens is switched on and the first strips absorb radiation having the appropriate polarization. Since the second strips do not absorb radiation, the component acts as a Fresnel lens. If the component is switched off, i.e. the nano-elements are oriented perpendicular to the plane of drawing, the first strips are not absorbing and the component is a plane parallel plate. For clearness sake only a few strips have been shown in FIG. 7, but in practice the number of strips may be much larger. The same holds for the number of nano-elements. The Fresnel structure may be manufactured in the same way as described hereinabove for the linear grating.

1. A programmable optical component for spatially controlling the intensity of a beam of radiation, which component comprises a programmable layer which is divided in programmable elements, characterized in that each programmable element comprises bendable nano-elements which are switchable between a non-bend state and a bend state by means of a driver field.

2. A component as claimed in claim 1, characterized in that it comprises a substrate, an electrode configuration of first and second electrode portions, which configuration defines the programmable element areas, and a nano-elements embedding medium on top of the electrode configuration.

3. A component as claimed in claim 2, characterized in that an electrically isolating layer is arranged between the electrode configuration and the nano-elements embedding medium.

4. A component as claimed in claim 2,characterized in that each nano-element is arranged in an insulating region.

5. A component as claimed in claim 2, characterized in that the nano-elements embedding medium is an insulating fluid.

6. A component as claimed in claim 2, characterized in that the first and second electrode portions form a pair of interdigitated electrodes.

7. A component as claimed in claim 2, characterized in that the electrode configuration is embedded in a planarizing layer and the nano-elements embedding layer is arranged on the planarizing layer.

8. A component as claimed in claim 2, characterized in that a second electrode configuration is arranged at the side of the nano-elements embedding medium remote from the medium side facing the substrate.

9. A component as claimed in claim 1, characterized in that the nano-elements have a diameter in the range from 1 nm to 50 nm.

10. A component as claimed in claim 1, characterized in that the nano-elements are nanowires.

11. A component as claimed in claim 1, characterized in that the nano-elements are nanotubes.

12. A component as claimed in claim 1, characterized in that the nano-elements comprise a semiconductor material.

13. A component as claimed in claim 11, characterized in that the nanotubes are carbon nanotubes.

14. A component as claimed in claim 13, characterized in that the nanotubes are single wall nanotubes.

15. A component as claimed in claim 1, characterized in that it is a transmission component.

16. A component as claimed in claim 1, characterized in that it is a reflective component.

17. A component as claimed in claim 1, forming a switchable diffraction grating, wherein the programmable elements have an elongated shape and constitute grating strips, which alternate with nano-elements less intermediate strips.

18. A component as claimed in claim 17, forming a linear grating, wherein the programmable elements all extend in the same direction.

19. A component as claimed in claim 17, forming a two-dimensional grating having first programmable element extending in a first direction and second programmable elements extending in a second direction, different from the first direction, which first programmable elements are arranged in first surface areas and which second programmable elements are arranged in second surface areas alternating with the first surface areas.

20. A component as claimed in claim 1, forming a switchable Fresnel lens, wherein the programmable elements have an annular shape and constitute Fresnel lens zones, which alternate with nano-elements less intermediate annular strips.

21. A component as claimed in claim 1, forming a mask having a changeable mask pattern, wherein the programmable elements constitute pixels, which are arranged in a two-dimensional structure.

22. A device for scanning an optical information carrier of a first type having a first information density and an optical information carrier of a second type having a second information density, which device comprises a radiation source unit supplying a first radiation beam having a first wavelength for cooperating with the first type information carrier and a second radiation beam having a second wavelength for cooperating with the second type of record carrier, and an objective system for focussing the first and second beam to a first and second scanning spot in the information layer of the first and second type information carrier, characterized in that it comprises at least one component as claimed in claim 18.

23. A device as claimed in claim 22, characterized in that the component is a beam-combining diffraction grating and in that such a grating is arranged in at least one of the following optical path portions:
between the radiation source unit and the objective system,
between the objective system and a radiation-sensitive detection system for receiving radiation from the information layers.

24. A device as claimed in claim 22, characterized in that the component is a three-spots diffraction grating and is arranged between the radiation source unit and the objective system.

25. A lithographic process for producing device features in at least one layer of a substrate, which process comprises transferring a mask pattern into the substrate layer by means of a projection apparatus, characterized in that use is made of a mask as claimed in claim 21.
